(19) United States
(12) Patent Application Publication
(10) Pub. No.: US 2011/0008938 A1
(43) Pub. Date: Jan. 13, 2011

(54) THIN FILM AND METHOD FOR MANUFACTURING SEMICONDUCTOR DEVICE USING THE THIN FILM

(75) Inventors: Yoshihiro Kato, Yamanashi (JP); Noriaki Fukiage, Hyogo (JP)

Correspondence Address: CANTOR COLBURN LLP, 20 Church Street, 22nd Floor, Hartford, CT, 06103, US

(73) Assignee: TOKYO ELECTRON LIMITED, Tokyo (JP)

(21) Appl. No.: 12/867,823

(22) PCT Filed: Feb. 12, 2009
(86) PCT No.: PCT/JP2009/052301

§ 371 Date: Aug. 16, 2010

(30) Foreign Application Priority Data
Feb. 19, 2008 (JP) 2008-037263

(51) Int. Cl. H01L 21/8238; H01L 21/336; H01L 29/06; H01L 21/302

(52) U.S. Cl. 438/218; 438/294; 257/629; 438/689; 257/E21.632; 257/E21.409; 257/E29.006; 257/E21.214

(57) ABSTRACT

Disclosed is a thin film which is used in the production process of a semiconductor device. The thin film contains germanium, silicon, nitrogen and hydrogen.

### BACKGROUND OF THE INVENTION

1. Technical Field

The present invention relates to a thin film used in processes of forming the film on a semiconductor substrate, using the film in a particular function, and then removing the film, and a method of manufacturing a semiconductor by using the film.

2. Background

Integrated circuits have achieved high integration and high performance through a reduction in the pattern size. However, as the pattern size of the integrated circuits has become a nanometer level, it is hard to anticipate a further improvement in the transistor performance through the reduction in the pattern size.

In an effort to resolve the problem and improve the quality of transistors, a technology has been considered to improve the carrier mobility. As a method for improving the carrier mobility, there is a technology of applying a stress to a channel by depositing a silicon nitride (SiN) film, which has a tensile stress (in the case of nMOS transistor) or a compressive stress (in the case of pMOS transistor), directly on a transistor. See, for example, Japanese Patent Laid-Open Publication No. 2007-19515.

This technology will now be briefly described with reference to FIG. 26. A source 12, a drain 13, a gate insulation film 14, a gate electrode 15, a side wall spacer 16, and a nickel silicide 17 are formed on a silicon substrate 11. And then a silicon nitride film (SiN film) 18 or 19, which is also called a stress liner, is formed on top of the deposited structure. The SiN film 18 on the nMOS transistor has a tensile stress and applies the tensile stress to the channel area 20. Meanwhile, the SiN film 19 deposited on the pMOS transistor has a compressive stress and applies the compressive stress to the channel area 21. As a result, the mobility of electrons increases in the nMOS transistor, and the mobility of holes increases in the pMOS transistor.

However, since the side wall spacer 16 is deposited under the SiN film having the stress and the stress is applied through the spacer, the stress actually applied to the channel is not so large.

In order to more effectively apply the stress, it is reportedly preferable to remove the side wall spacer 16 and directly deposit the SiN film 18 or 19 around the gate. See, for example, Japanese Patent Laid-Open Publication No. 2007-49166.

Side wall spacer 16 is a layer originally used as a mask for ion injection. The gate electrode 15 is first etched, an area so-called an extension is formed through ion injection, and the side wall spacer is then formed. Then, ion injection of a deep diffusion layer is performed using the side wall spacer as a mask, so that the formation of the source 12 and the drain 13 is completed.

Since the side wall spacer is used as a mask for ion injection as described above, the side wall spacer is required to be stable in the ion injection atmosphere and to be stable in the sulfuric acid/hydrogen peroxide mixture solution used when the resist used in the ion injection is removed. Therefore, the SN film is generally used as the side wall spacer.

As well known in the art, the SiN film is a stable film, which is not soluble in the sulfuric acid/hydrogen peroxide mixture solution, and only the phosphoric acid is used as an etching solution capable of solving the SiN film. However, even when the phosphoric acid is used, the etching is slow so that quite a long time is required for removing the side wall spacer. As a result, when the side wall spacer is removed, the nickel silicide 17 may also be etched, and the resistance of the diffusion layers (including the source 12 and the drain 13) may increase. Therefore, there has been a requirement for a side wall spacer technology capable of achieving a rapid etching, so as to prevent etching of the nickel silicide 17.

### SUMMARY

As described above, there has been a problem that, when the side wall spacer is removed in order to effectively apply a stress to the channel part, the nickel silicide on the source 12 and the drain 13 is also etched thereby increasing the resistance.

One of the goals of the present invention is to provide a thin film and a method of manufacturing a semiconductor device using the thin film, which can rapidly remove thin films, such as a side wall spacer, used in the semiconductor device without etching the other films including a nickel silicide film.

In order to accomplish this object, in accordance with a first aspect of the present invention, there is provided a thin film used in a process of manufacturing a semiconductor device, wherein the thin film comprises germanium, silicon, nitrogen, and hydrogen.

In accordance with a second aspect of the present invention, there is provided a method of manufacturing a semiconductor device, the method comprising: forming the thin film according to the first aspect; exposing the thin film to an etching; and removing the thin film remaining after the etching.

In accordance with a third aspect of the present invention, there is provided a method of manufacturing a semiconductor device, the method comprising: forming a gate electrode on an active area in a semiconductor layer including the active area and a device isolation area; forming a side wall spacer on a side surface of the gate electrode by using the thin film according to the first aspect; forming a pair of source-and-drain areas in the active area by injecting impurities in the active area by using the device isolation area, the gate electrode, and the side wall spacer as masks; coating a metal film on the semiconductor layer, the device isolation area, the side wall spacer, and the gate electrode; reacting the metal film with the semiconductor layer and the gate electrode, so as to partially lower a resistance of the source-and-drain areas and the gate electrode; removing a non-reacted portion of the metal film by using an etching agent, which can easily etch the non-reacted portion of the metal film and cannot easily etch the device isolation area, a resistance-lowered portion of the gate electrode, a resistance-lowered portion of the source-and-drain areas, and the side wall spacer; and removing the side wall spacer by using an etching agent, which can easily etch the side wall spacer and cannot easily etch the device isolation area, the resistance-lowered portion of the gate electrode, and the resistance-lowered portion of the source-and-drain areas.

In accordance with a fourth aspect of the present invention, there is provided a method of manufacturing a semiconductor device, the method comprising: forming a gate electrode on each of a first conductive active area and a second conductive active area in a semiconductor layer including the first conductive active area, the second conductive active area, and a device isolation area; forming side wall spacers on side surfaces of the gate electrode formed on the first conductive active area and on side surfaces of the gate electrode formed on the second conductive active area by using the thin film according to the first aspect; covering an area in the semiconductor layer, at which a first conductive transistor is formed, by using a first mask material; forming a pair of second conductive source-and-drain areas in the first conductive active area by injecting impurities in the first conductive active area by using the device isolation area, the gate electrode formed on the first conductive active area, the side wall spacers formed on the gate electrode, and the first mask material as masks; removing the first mask material, and then covering an area in the semiconductor layer, at which a second conductive transistor is formed, by using a second mask material; forming a pair of first conductive source-and-drain areas in the second conductive active area by injecting impurities in the second conductive active area by using the device isolation area, the gate electrode formed on the second conductive active area, the side wall spacers formed on the gate electrode, and the second mask material as masks; removing the second mask material and then coating a metal film on the semiconductor layer, the device isolation area, the side wall spacer, and the gate electrode; reacting the metal film with the semiconductor layer and the gate electrode, so as to partially lower a resistance of the source-and-drain areas and the gate electrode; removing a non-reacted portion of the metal film by using an etching agent, which can easily etch the non-reacted portion of the metal film and cannot easily etch the device isolation area, a resistance-lowered portion of the gate electrode, a resistance-lowered portion of the source-and-drain areas, and the side wall spacer; and removing the side wall spacer by using an etching agent, which can easily etch the side wall spacer and cannot easily etch the device isolation area, is the resistance-lowered portion of the gate electrode, and the resistance-lowered portion of the source-and-drain areas.

### BRIEF DESCRIPTION OF THE DRAWINGS

FIG. 1a illustrates etching rates of a GeSiNH film according to the first embodiment of the present invention.

FIG. 1b is a graph drawn by the numerical values shown in FIG. 1a.

FIG. 2 shows, as a reference example, the change in the etching rate for the DHF before and after oxygen plasma ashing of the GeSiCOH film.

FIG. 3 shows a result of an analysis of the GeSiCOH film as a reference example.

FIG. 4 shows the change in the etching rate for the DHF before and after oxygen plasma ashing of a GeSiNH film according to the first embodiment of the present invention.

FIG. 5 shows a result of an analysis of the structure of a GeSiNH film according to the first embodiment of the present invention.

FIG. 6 shows a result of an analysis of the composition of the GeSiNH film a GeSiNH film according to the first embodiment of the present invention.

FIG. 7 shows etching rates of a GeSiNH film according to the first embodiment of the present invention after the oxygen plasma ashing.

FIG. 8a shows etching rates of a GeSiNH film according to the second embodiment of the present invention after the oxygen plasma ashing.

FIG. 8b is a graph drawn by the numerical values shown in FIG. 8a.

FIG. 9a shows etching rates of a GeSiNH film according to the second embodiment of the present invention after the oxygen plasma ashing.

FIG. 9b is graph drawn by the numerical values shown in FIG. 9a.

FIG. 10 shows the N₂ flow rate dependency of the etching rate for the phosphoric acid after the oxygen plasma ashing in the GeSiNH film according to the second embodiment.

FIG. 11 shows the N₂ flow rate dependency of the etching rate for the DHF after the oxygen plasma ashing in the GeSiNH film according to the second embodiment.

FIG. 12a shows the etching rates of a GeSiCNH film according to the third embodiment after the oxygen plasma ashing.

FIG. 12b is a graph drawn by using the numerical values of FIG. 12a.

FIG. 13 is a sectional view for illustrating a method of manufacturing a semiconductor device according to the fourth embodiment of the present invention.

FIG. 14 is a sectional view for illustrating a method of manufacturing a semiconductor device according to the fourth embodiment of the present invention.

FIG. 15 is a sectional view for illustrating a method of manufacturing a semiconductor device according to the fourth embodiment of the present invention.

FIG. 16 is a sectional view for illustrating a method of manufacturing a semiconductor device according to the fourth embodiment of the present invention.

FIG. 17 is a sectional view for illustrating a method of manufacturing a semiconductor device according to the fourth embodiment of the present invention.

FIG. 18 is a sectional view for illustrating a method of manufacturing a semiconductor device according to the fourth embodiment of the present invention.

FIG. 19 is a sectional view for illustrating a method of manufacturing a semiconductor device according to the fourth embodiment of the present invention.

FIG. 20 is a sectional view for illustrating a method of manufacturing a semiconductor device according to the fourth embodiment of the present invention.

FIG. 21 is a sectional view for illustrating a method of manufacturing a semiconductor device according to the fourth embodiment of the present invention.

FIG. 22 is a sectional view for illustrating a method of manufacturing a semiconductor device according to the fourth embodiment of the present invention.

FIG. 23 is a sectional view for illustrating a method of manufacturing a semiconductor device according to the fourth embodiment of the present invention.

FIG. 24 is a sectional view for illustrating a method of manufacturing a semiconductor device according to the fourth embodiment of the present invention.

FIG. 25 is a sectional view for illustrating a method of manufacturing a semiconductor device according to the fourth embodiment of the present invention.

FIG. 26 is a sectional view of a conventional transistor according to the prior art.

### DETAILED DESCRIPTION OF THE EXEMPLARY EMBODIMENTS

In order to achieve the above-mentioned object, two methods can be taken into consideration. One method is to provide a solution capable of etching the SiN film without etching the nickel silicide, and the other method is to provide a solution capable of achieving a rapid etching within the phosphoric acid in a short time.

The present embodiment aims for the latter and provides a film, which can completely perform especially the function as a side wall spacer and is easily etched in the phosphoric acid.

Hereinafter, properties required for the side wall spacer are briefly described below.

1) Since the side wall spacer is originally used as a mask for ion injection, the side wall spacer is required to have a property that does not change in the ion injection process.

2) The side wall spacer shall not be etched in a process of removing the resist used in the ion injection (a oxygen plasma ashing and a residue removal using a sulfuric acid/hydrogen peroxide mixture solution) or a process of removing a natural oxide film (removal of a natural oxide film using a dilute hydrofluoric acid).

3) The side wall spacer is required to have a property that does not change by the process of removing the resist, especially by the oxygen plasma ashing.

Especially, it is an important requisite for the side wall spacer that the side wall spacer is barely etched by a dilute hydrofluoric acid or a sulfuric acid/hydrogen peroxide mixture solution, is easily etched by a phosphoric acid, and has a property that is not changed by the oxygen plasma ashing.

An object of the present embodiment is to provide a film, which is not dissolved by a dilute hydrofluoric acid or a sulfuric acid/hydrogen peroxide mixture solution, is easily etched by a phosphoric acid, and has a property that is not easily changed by the oxygen plasma ashing.

### First Embodiment

As a result of repeated prudent examinations by the inventor in order to achieve the object, it has been understood that a GeNH film formed by using GeH₄ (Germane)+N₂ (Nitrogen) as a process gas has a high etching rate for the phosphoric acid. Further, it has been noticed that, by adding SiH₄ (monosilane) to the process gas and then changing the quantity of the added monosilane, it is possible to control the etching rate for the phosphoric acid and the etching rate for the SPM (sulfuric acid/hydrogen peroxide mixture solution), respectively.

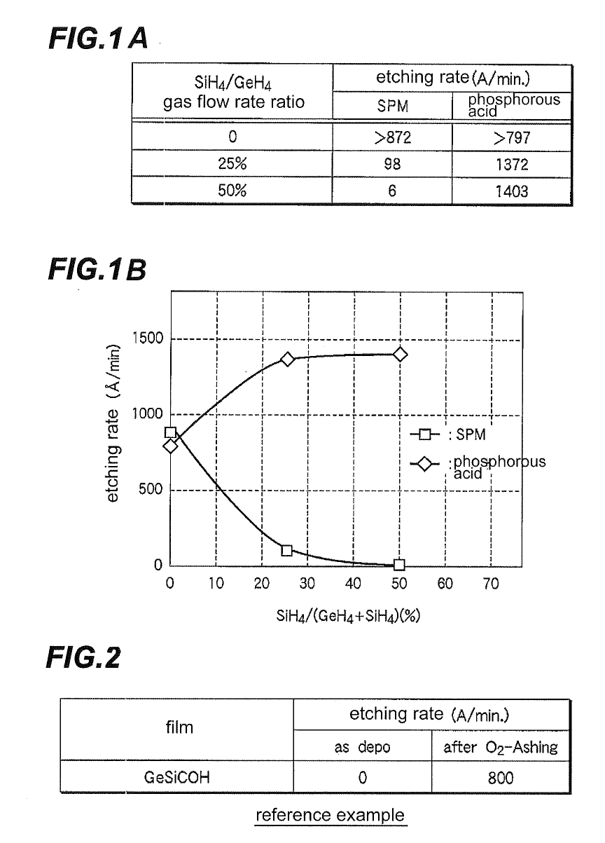

FIGS. 1a and 1b show an SiH₄/GeH₄ ratio dependency of the etching rate for the phosphoric acid and the etching rate for the SPM of a GeSiNH film, according to a first embodiment of the present invention. FIG. 1a is a table illustrating the numerical values, and FIG. 1b is a graph drawn by the numerical values.

As shown in FIGS. 1a and 1b, in the case of a film formed without adding SiH₄ (SiH₄/(GeH₄+SiH₄)=0%), the etching rate for the phosphoric acid has a value of not less than 797 A/min (79.7 nm/min), and the etching rate for the SPM has a value of not less than 872 A/min(87.2 nm/min).

Further, in the case of a film formed by adding SiH₄, when SiH₄/(GeH₄+SiH₄)=25%, the etching rate for the phosphoric acid increased to 1372 A/min(137.2 nm/min), and the etching rate for the SPM decreased to 98 A/min(9.8 nm/min).

It has been found that, by adding SiH₄ to the process gas (GeH₄+N₂) as described above, it is possible to form a film, which is easily etched by the phosphoric acid and is barely etched by the SPM.

Further, when the quantity of the added SiH₄ is increased and SiH₄/(GeH₄+SiH₄)=50%, the etching rate for the phosphoric acid further increased to 1403 A/min (140.3 nm/min), and the etching rate for the SPM further decreased to 6 A/min (0.6 nm/min).

It has been found that, by adding SiH₄ to the process gas (GeH₄+N₂) and then increasing the quantity of the added SiH₄ as described above, it is possible to further reinforce the property of the film, which is easily etched by the phosphoric acid and is barely etched by the SPM.

As described above, the GeNH film formed by using a nitrogen and a hydrogen compound of germanium (GeH₄ and N₂ in the present embodiment) as a process gas has a high etching rate for the phosphoric acid. Further, the GeSiNH film formed by adding SiH₄ to the process gas is more easily etched by the phosphoric acid than the GeNH film, and is more barely etched by the SPM than the GeNH film. A film having the properties as described above, a GeSiNH film in the present embodiment, is available as a thin film material for the side wall spacer.

It has also been found that the GeSiNH film has a property that is not easily changed even by an oxygen plasma ashing.

For example, as a film having the same property as the GeSiNH film, there is a GeSiCOH film. Like the GeSiNH film, the GeSiCOH film is easily etched by the phosphoric acid and is barely etched by the SPM. Further, since the GeSiCOH film is also barely etched by the DHF (dilute hydrofluoric acid), the GeSiCOH is one of important materials for the side wall spacer. However, the GeSiCOH film has a property changing before and after the oxygen plasma ashing.

Specifically, although the original GeSiCOH film itself is barely etched by the DHF, it becomes easily etchable by the DHF after the oxygen plasma ashing. FIG. 2 shows, as a reference example, the change in the etching rate for the DHF before and after the oxygen plasma ashing of the GeSiCOH film. Further, film formation conditions of the GeSiCOH film shown in FIG. 2 are as follows.

Film formation apparatus: parallel plate-type plasma CVD apparatus

Gas flow rate: TMGe/SiH₄/CO₂=80/120/1500 sccm

Upper part RF: 200 W

Pressure: 267 Pa

Gap: 18 mm

Temperature (susceptor temperature): 300° C.

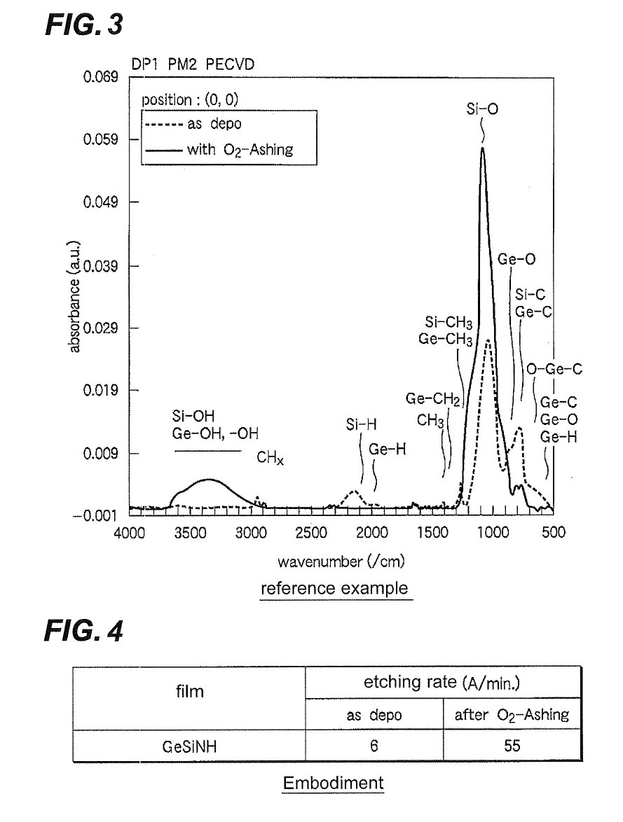

As noted from FIG. 2, the GeSiCOH film before the oxygen plasma ashing (as depo) is not dissolved by the DHF. In the present embodiment, the etching rate is “0” and has not been etched at all. In contrast, the GeSiCOH film after the oxygen plasma ashing (after O₂-Ashing) is easily dissolved by the DHF. In the present embodiment, the etching rate is 800 A/min (80 nm/min). Based on this fact, it is supposed that the structure of the GeSiCOH film changes before and after the oxygen plasma ashing. FIG. 3 shows a result of an analysis of the structure of the GeSiCOH film by using the InfraRed Spectroscopy (R).

As shown in FIG. 3, in comparison between the GeSiCOH film before being subjected to the oxygen plasma ashing (as depo) and the GeSiCOH film after being subjected to the oxygen plasma ashing (with O₂-Ashing), especially the intensity of the spectrum indicating the Si—O bond shows a remarkable increase. This implies that the quantity of the Si—O bonds has been remarkably increased. Therefore, it is possible to suppose that the GeSiCOH film has been oxidized through an exposure to the oxygen plasma.

As described above, the GeSiCOH film is oxidized by the oxygen plasma ashing, and changes its property from insoluble to the DHF to soluble to the DI-IF.

In contrast, such a property change is suppressed in the GeSiNH film according to the present embodiment. FIG. 4 shows the change in the etching rate for the DHF before and after oxygen plasma ashing of the GeSiNH film. Further, film formation conditions of the GeSiNH film shown in FIG. 4 are as follows.

Film formation apparatus: parallel plate-type plasma CVD apparatus

Gas flow rate: GeH₄/SiH₄/N₂=40/20/500 sccm

Upper RF: 500/100 W

Pressure: 267 Pa

Gap: 18 mm

Temperature (susceptor temperature): 300° C.

As noted from FIG. 4, the GeSiNH film before the oxygen plasma ashing (as depo) is barely dissolved by the DHF. In the present embodiment, the etching rate is 6 A/min (0.6 nm/min). In contrast, the GeSiNH film after the oxygen plasma ashing (after O₂-Ashing) is dissolved by the DHF somewhat easier than the GeSNH film before the oxygen plasma ashing. However, in the GeSiNH film after the oxygen plasma ashing, the etching rate is 55 A/min (5.5 nm/min), and the etching rate for the DHF has been improved about 1/14 to 1/15 in comparison with the GeSiCOH film. FIG. 5 shows the result of an analysis of the structure of the GeSiNH film by using the InfraRed Spectroscopy (IR).

Referring to FIG. 5, in comparison between the GeSiNH film before being subjected to the oxygen plasma ashing (as depo) and the GeSiNH film after being subjected to the oxygen plasma ashing (with O₂-Ashing), nearly no change is observed in the spectrum. This implies that the GeSiNH film has a property that is not easily changed, for example, not easily oxidized, even when the GeSiNH film is exposed to the oxygen plasma.

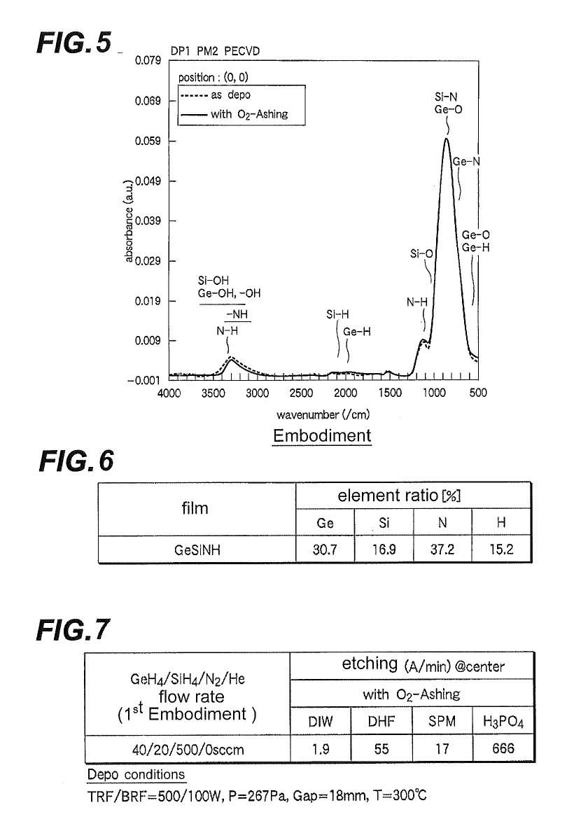

FIG. 6 shows the result of an analysis of the composition of the GeSiNH film by using the Rutherford Backscattering Spectrometry (RBS) and the Hydrogen Forwardscattering Spectrometry (HFS).

As shown in FIG. 6, main elements included in the GeSiNH film are four elements including germanium (Ge), silicon (Si), nitrogen (N), and hydrogen (H), and existence ratios of each of the four elements is 30.7%, 16.9%, 37.2%, and 15.2%, respectively.

For example, the GeSiNH film having the composition described above has a property, which is not easily changed even after the oxygen plasma ashing and cannot be easily dissolved even after the oxygen plasma ashing.

As described above, according to the first embodiment of the present invention, it is possible to form a film (the GeSiNH film in the present embodiment), which is available as a material for a side wall spacer exposable to a harsh environment, such as a resist ashing process using the oxygen plasma and a natural oxide film removal process using the DHF.

### Second Embodiment

The first embodiment provides a GeSiNH film, which has a property that is not easily degraded by the oxygen plasma ashing and is not easily dissolved by the DHF even after the oxygen plasma ashing. FIG. 7 shows the etching rates of the GeSiNH film after the oxygen plasma ashing with respect to various etching agents, wherein all the etching rates correspond to etching rates at the center of the wafer.

As shown in FIG. 7, in comparison with the GeSiCOH film, although the GeSiNH film according to the first embodiment maintains its property of being barely dissolved by the DHF, its etching rate is 55 A/min (5.5 nm/min). Further, the etching rate for the SPM after the oxygen plasma ashing is 17 A/min (1.7 nm/min). Moreover, the etching rate for the phosphoric acid (H₃PO₄) is 666 A/min (66.6 nm/min), and the etching rate for the deionized water (DIW) is 1.9 A/min (0.19 nm/min).

The second embodiment of the present invention is intended to further decrease, for example, the etching rates for the SPM and the DHF after the oxygen plasma ashing.

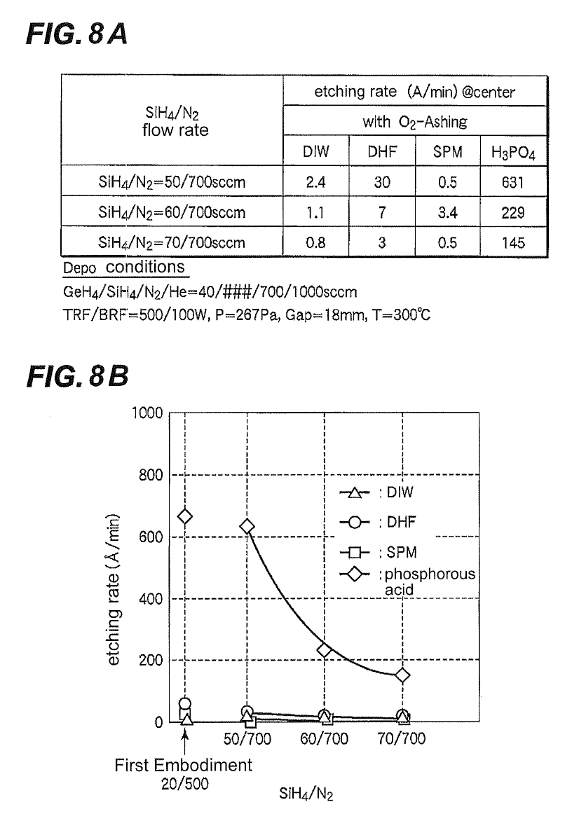

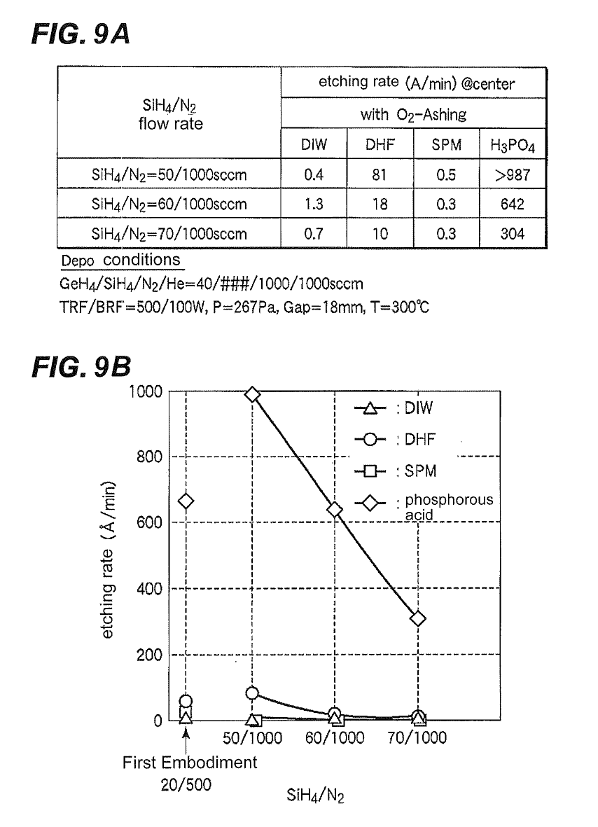

FIGS. 8a and 9a show the SiH₄/N₂ ratio dependency of the GeSiNH film according to the second embodiment after the oxygen plasma ashing with respect to various etching agents. FIG. 8b is a graph drawn by using the numerical values of FIG. 8a, and FIG. 9b is a graph drawn by using the numerical values of FIG. 9a. Further, the numerical values of the GeSiNH film according to the first embodiment are also plotted in FIGS. 8b and 9b.

The second embodiment is different from the first embodiment, particularly in that both the flow rate of SiH₄ and the flow rate of N₂ are increased, and He is newly employed as the process gas in the second embodiment

FIGS. 8a and 8b correspond to a case in which GeH₄, SiH₄, N₂, and He are used as the process gases, GeH₄ has a fixed flow rate of 40 sccm, N₂ has a fixed flow rate of 700 sccm, and He has a fixed flow rate of 1000 sccm, while SiH₄ has changing flow rates of 50 sccm, 60 sccm, and 70 sccm.

Similarly, FIGS. 9a and 9b correspond to a case in which each of GeH₄, N₂, and He has a fixed flow rate of 40 sccm, 1000 sccm, 1000 sccm, respectively, while changing the flow rate of SiH₄ with 50 sccm, 60 sccm and 70 sccm.

The other film formation conditions except for the gas flow rate are the same as those of the first embodiment, which are as follows.

Film formation apparatus: parallel plate-type plasma CVD apparatus

Upper RF/Lower RF: 500/100 W

Pressure: 267 Pa

Gap: 18 mm

Temperature (susceptor temperature): 300° C.

(SiH₄ flow rate dependency of etching rate for the SPM)

First, as shown in FIGS. 8a and 9a, in comparison with the first embodiment, when the flow rate of SiH₄ is increased, the etching rate for the SPM after the oxygen plasma ashing is degraded. For example, although the etching rate for the SPM after the oxygen plasma ashing is 17 A/min (1.7 nm/min) in the first embodiment, the etching rate for the SPM after the oxygen plasma ashing is lowered into a range of 0.3 to 3.4 A/min (0.03 to 0.34 nm/min) by increasing the flow rate of SiH₄ in the second embodiment

As described above, by increasing the flow rate of SiH₄, it is possible to lower the etching rate for the SPM after the oxygen plasma ashing.

Therefore, preferable ranges of the flow rates of SiH₄ in consideration of the etching rate for the SPM are as follows, when they are converted to flow rate ratios of SiH₄/N₂.

SiH₄/N₂=50/700 sccm: 6.67% (={50/(50+700)}×100%)

SiH₄/N₂=60/700 sccm: 7.89% (={60/(60+700)}×100%)

SiH₄/N₂=70/700 sccm: 9.09% (={70/(70+700)}×100%)

SiH₄/N₂=50/1000 sccm: 4.76% (={50/(50+1000)}×100%)

SiH₄/N₂=60/1000 sccm: 5.66% (={60/(60+1000)}×100%)

SiH₄/N₂=70/1000 sccm: 6.54% (={70/(70+1000)}×100%)

As noted from the above, by controlling the flow rate so that the flow rate ratio of SiH₄/N₂ is specifically larger than or equal to 4.76% and smaller than or equal to 9.09%, and is practically larger than or equal to 4% and smaller than or equal to 10%, it is possible to obtain a GeSiNH film capable of lowering the etching rate for the SPM after the oxygen plasma ashing.

SiH₄ flow rate dependency of etching rate for the DHF

Further, as shown in FIGS. 8a and 9a, in comparison with the first embodiment, when the flow rate of SiH₄ is increased, the etching rate for the DHF after the oxygen plasma ashing also is degraded. For example, although the etching rate for the DHF after the oxygen plasma ashing is 55 A/min (5.5 nm/min) in the first embodiment, the increase in the flow rate of SiH₄ in the second embodiment causes lowering of the etching rate for the DHF after the oxygen plasma ashing into a range of 3 to 30 A/min (0.3 to 3 nm/min), while increasing the etching rate to 81 A/min (8.1 nm/min) in some interval. However, an inclination is confirmed from FIGS. 8a and 8b in which, when the flow rate of N₂ is 700 sccm and the flow rate of SiH₄ is gradually increased from 50 sccm through 60 sccm to 70 sccm, the etching rate for the DHF after the oxygen plasma ashing is gradually lowered from 30 A/min (3 nm/min) through 7 A/min (0.7 nm/min) to 3 A/min (0.3 nm/min) according to the increase of the flow rate of N₂.

This inclination is, as shown in FIGS. 9a and 9b, the same as in the case in which the flow rate ratio of SiH₄/N₂ is gradually increased from 50/1000 sccm through 60/1000 sccm to 70/1000 sccm while fixing the flow rate of N₂ at 1000 sccm. In the present embodiment, the etching rate for the DHF after the oxygen plasma ashing shows a gradually lowering from 81 A/min (8.1 nm/min) through 18 A/min (1.8 nm/min) to 10 A/min (1 nm/min).

From this result, by increasing the flow rate of SiH₄, it is possible to further lower the etching rate for the DHF after the oxygen plasma ashing.

Especially, the etching rate for the DHF is required to secure a value smaller than or equal to 20 A/min (2 nm/min), in order to prevent the loss of the side wall spacer at the time of for example, removing the natural oxide film. Including this viewpoint, in consideration of the etching rate for the DHF, preferable ranges of the flow rates of SiH₄ are as follows when they are converted to flow rate ratios of SiH₄/N₂.

SiH₄/N₂=60/700 sccm: 7.89%

SiH₄/N₂=70/700 sccm: 9.09%

SiH₄/N₂=60/1000 sccm: 5.66%

SiH₄/N₂-70/1000 sccm: 6.54%

As noted from the above, by controlling the flow rate so that the flow rate ratio of SiH₄/N₂ is specifically larger than or equal to 5.66% and smaller than or equal to 9.09%, and is practically larger than or equal to 5% and smaller than or equal to 10%, it is possible to obtain a GeSiNH film capable of lowering the etching rate for the DHF after the oxygen plasma ashing.

Further, it is also confirmed from FIGS. 8a and 9a that the etching rate for the deionized water (DIW) after the oxygen plasma ashing can be continuously suppressed to be low in spite of the increase in the flow rate of SiH₄.

As described above, even when the flow rate of SiH₄ is further increased in comparison with the first embodiment, the property required for the side wall spacer is not damaged.

SiH₄ flow rate dependency of etching rate for the phosphoric acid

However, when the flow rate of SiH₄ is increased too much, the etching rate for the phosphoric acid is lowered too much. For example, if the flow rate of SiH₄ is 70 sccm, the etching rate for the phosphoric acid is 145 A/min (14.5 nm/min) when the flow rate of N₂ is 700 sccm, and is 304 A/min (30.4 nm/min) when the flow rate of N₂ is 1000 sccm.

In order to improve the throughput, the etching rate for the phosphoric acid is required to secure a value larger than or equal to 480 A/min (48 nm/min). Including this viewpoint, in consideration of the etching rate for the phosphoric acid, preferable ranges of the flow rates of SiH₄ are as follows when they are converted to flow rate ratios of SiH₄/N₂.

SiR₄/N₂=50/700 sccm: 6.67%

SiH₄/N₂=60/1000 sccm: 5.66%

SiH₄/N₂=50/1000 sccm: 4.76%

As noted from the above, by controlling the flow rate so that the flow rate ratio of SiH₄/N₂ is specifically larger than or equal to 4.76% and smaller than or equal to 6.67%, and is practically larger than or equal to 4% and smaller than or equal to 7%, it is possible to obtain a GeSiNH film capable of maintaining a high etching rate for the phosphoric acid after the oxygen plasma ashing.

N₂ flow rate dependency of etching rate for the phosphoric acid

Next, the case in which the flow rate of N₂ is increased is discussed.

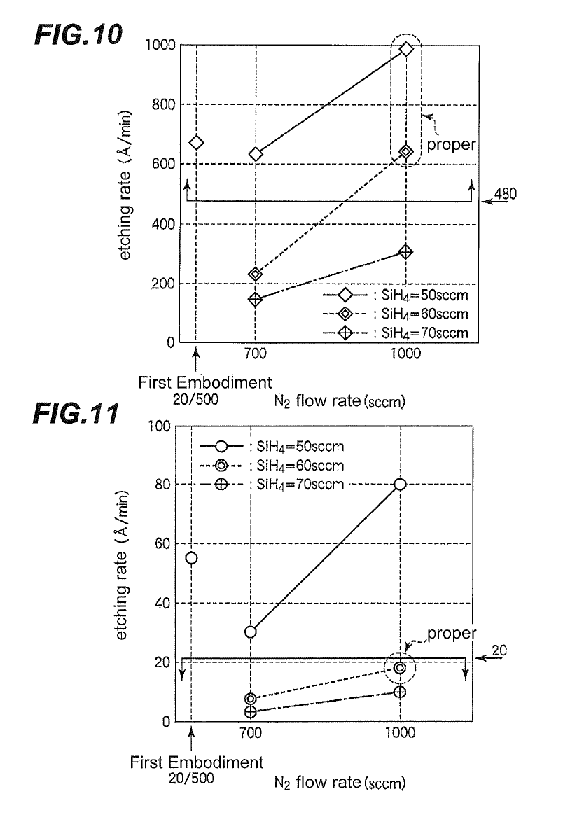

FIG. 10 shows the N₂ flow rate dependency of the etching rate for the phosphoric acid after the oxygen plasma ashing in the GeSiNH film, according to the second embodiment. FIG. 10 is a graph drawn by using the numerical values of the etching rates for the phosphoric acid (H₃PO₄) shown in FIGS. 8a and 9a. Further, the numerical values of the etching rates of the GeSiNH film according to the first embodiment for the phosphoric acid are also plotted in FIG. 10 for reference.

As illustrated in FIG. 10, when the N₂ flow rate is increased from 700 sccm to 1000 sccm, the etching rate for the phosphoric acid is increased.

In order to improve the throughput, the etching rate for the phosphoric acid is required to secure a value larger than or equal to 480 A/min (48 nm/min). Including this viewpoint and in a viewpoint that 1000 sccm is advantageous as the flow rate of N₂, preferable ranges for the flow rate ratio of SiH₄/N₂ are as follows.

SiH₄/N₂=60/1000 sccm: 5.66%

SiH₄/N₂=50/1000 sccm: 4.76%

As noted from the above, by controlling the flow rate so that the flow rate ratio of SiH₄/N₂ is specifically larger than or equal to 4.76% and smaller than or equal to 5.66%, and is practically larger than or equal to 4% and smaller than or equal to 6%, it is possible to obtain a GeSiNH film capable of maintaining the etching rate for the phosphoric acid after the oxygen plasma ashing at a high value larger than or equal to, for example, 480 A/min (48 nm/min), even when the flow rate of N₂ has been set to, for example, 1000 sccm.

N₂ Flow Rate Dependency of Etching Rate for DHF

FIG. 11 shows the N₂ flow rate dependency of the etching rate for the DHF after the oxygen plasma ashing in the GeSiNH film, according to the second embodiment. FIG. 11 is a graph drawn by using the numerical values of the etching rates for the DHF shown in FIGS. 8a and 9a. Further, the numerical values of the etching rates of the GeSiNH film according to the first embodiment for the DHF are also plotted in FIG. 11 for reference.

As noted from FIG. 11, when the N₂ flow rate is increased from 700 sccm to 1000 sccm, the etching rate for the DHF is increased.

As described above, the etching rate for the DHF should be suppressed to have a value smaller than or equal to 20 A/min (2 nm/min), in order to prevent the loss of the side wall spacer. In consideration of this viewpoint, 700 sccm rather than 1000 sccm should be selected as the flow rate of N₂. However, in consideration of the viewpoint for improving the throughput also, which requires the selection of 1000 sccm as the flow rate of N₂, a trade-off relation is established.

In consideration of the trade-off relation as described above, a preferred flow rate ratio for SiH₄/N₂ can be determined as follows.

SiH₄/N₂=60/1000 sccm: 5.66%

As noted from the above, by controlling the flow rate so that the flow rate ratio of SiH₄/N₂ is specifically 5.66%, and is practically larger than or equal to 5% and smaller than or equal to 6%, it is possible to obtain a GeSiNH film capable of maintaining the etching rate for the phosphoric acid after the oxygen plasma ashing at a high value larger than or equal to, for example, 480 A/min (48 nm/min), even when the flow rate of N₂ has been set to, for example, 1000 sccm.

Further, film formation conditions of the GeSiNH film are as follows.

Film formation apparatus: parallel plate-type plasma CVD apparatus

Gas flow rate: GeH₄/SiH₄/N₂/He=40/60/1000/1000 sccm

Upper RF/Lower RF: 500/100 W

Pressure: 267 Pa

Gap: 18 mm

Temperature (susceptor temperature): 300° C.

### Third Embodiment

The third embodiment is intended, like the second embodiment, to further decrease, for example, the etching rates for the SPM and the DHF after the oxygen plasma ashing.

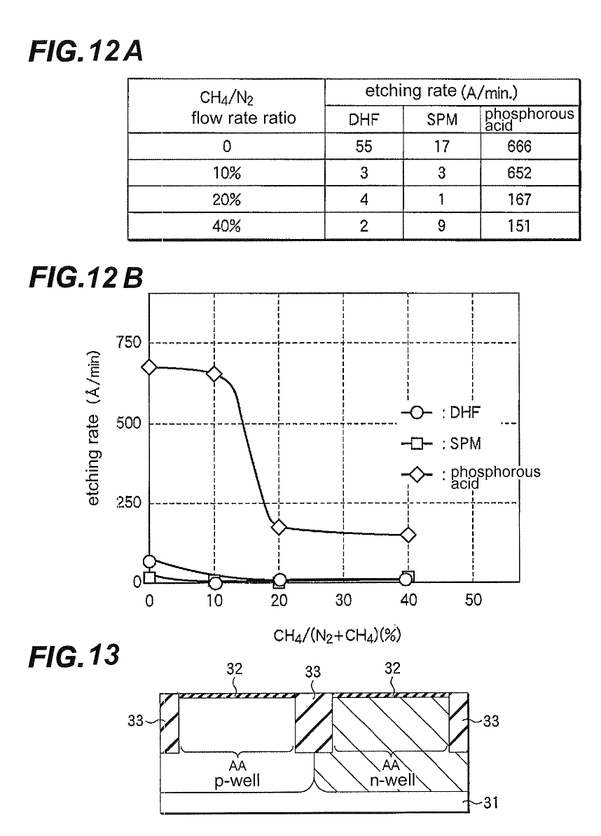

In the third embodiment, a gas containing carbon, for example, CH₄ (methane), is added to the process of forming the GeSiNH film according to the first embodiment described above. FIG. 12a shows the etching rates of the GeSiCNH film according to the third embodiment after the oxygen plasma ashing with respect to the DHF, the SPM, and the phosphoric acid. FIG. 12b is a graph drawn by using the numerical values of FIG. 12a.

FIGS. 12a and 12b correspond to a case in which GeH₄, SiH₄, CH₄, and N₂ are used as the process gases, GeH₄ has a fixed flow rate of 40 sccm, SiH₄ has a fixed flow rate of 20 sccm, and N₂ has a fixed flow rate of 500 sccm, while CH₄ has changing flow rates. The other film formation conditions except for the gas flow rate are as follows.

Film formation apparatus: parallel plate-type plasma CVD apparatus

Upper RF/Lower RF: 500/100 W

Pressure: 267 Pa

Gap: 18 mm

Temperature (susceptor temperature): 300° C.

FIGS. 12a and 12b show that the addition of a gas containing carbon, CH₄ in the present embodiment, has lowered both the etching rate for the DHF and the etching rate for the SPM.

As described above, by adding a gas containing carbon to the process of forming the GeSiNH film according to the first embodiment described above, it is also possible to lower both the etching rate for the DHF and the etching rate for the SPM.

Further, when CH₄ flows too much, the etching rate for the phosphoric acid is also lowered. In the present embodiment, when the flow rate ratio of CH₄/N₂ is larger than or equal to 20%, the etching rate is lowered to the level of 100 A/mim (10 nm/min). For the DHF and the SPM, in order to take a large etching selection ratio within the phosphoric acid, it is preferred that the flow rate ratio of CH₄/N₂ is smaller than or equal to 20%.

### Fourth Embodiment

The fourth embodiment corresponds to an example in which the GeSiNH film or GeSiCNH film according to the first to third embodiments described above is applied to a manufacture of a semiconductor device. The present embodiment corresponds to an example in which the GeSiNH film or GeSiCNH film is applied to especially the side wall spacer.

FIGS. 13 through 25 are sectional views for illustrating a method of manufacturing a semiconductor device according to the fourth embodiment of the present invention.

First, as shown in FIG. 13, a p-type semiconductor area (p-well in the present embodiment) for forming an n-channel type insulation gate field effect transistor, for example, an n-channel type MOSFET (nMOS transistor), and an n-type semiconductor area (n-well in the present embodiment) for forming a p-channel type insulation gate field effect transistor, for example, a p-channel type MOSFET (pMOS transistor), are formed on a semiconductor substrate 31 consisting of, for example, silicon using the conventional technology. Thereafter, on the semiconductor substrate 31, a device isolation area 33 is formed by using, for example, the STI (Shallow Trench Isolation) technology, and an Active Area (AA) is arranged through partitioning of the surface of the semiconductor substrate 31. A material of the device isolation area 33 is, for example, silicon oxide. Thereafter, a gate insulation film 32 consisting of silicon oxide is formed on the active area (AA) of the semiconductor substrate 31 by using, for example, the thermal oxidation method.

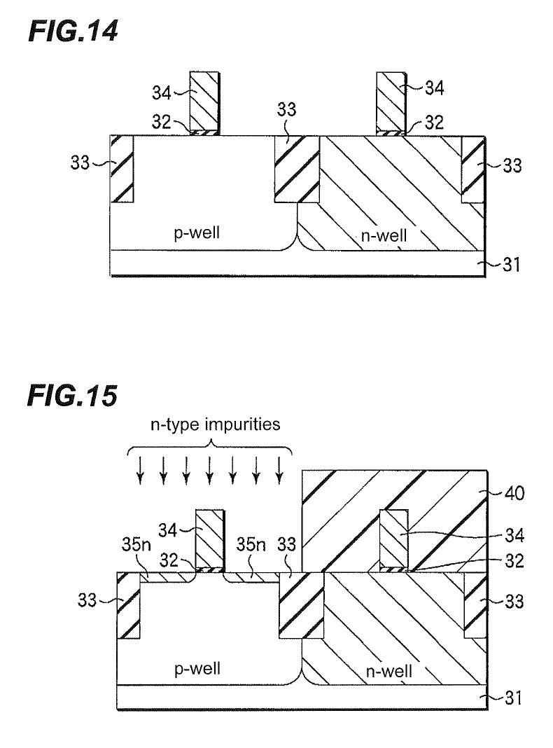

Next, as shown in FIG. 14, a conductive film is formed on the gate insulation film 32 and the device isolation area 33. Then, the conductive film is patterned through the photolithography method, so as to form gate electrodes 34 on the active area of the n-well and the active area of the p-well, respectively. As materials of the gate electrode 34, a polysilicon film or polysilicon germanium film containing, for example, arsenic (As) or phosphorous (P) as n-type impurity may be used in the case of the nMOS transistor. Further, in the case of the pMOS transistor, a polysilicon film or polysilicon germanium film containing, for example, boron (B) as p-type impurity may be used. Otherwise, a polysilicon film that does not contain impurity is first formed, and the polysilicon film is then patterned through the photolithography, so as to form the gate electrode 34. Then, n-type impurities may be injected to the p-well and the gate electrode 34 formed on the p-well, and p-type impurities may be injected to the n-well and the gate electrode 34 formed on the n-well.

Next, as shown in FIG. 15, a photoresist 40 is coated on the n-well on which a pMOS transistor is formed later. Then, an extension 35n of the nMOS transistor is formed through the ion injection of n-type impurities, such as, for example, arsenic, into the exposed p-well by using the device isolation area 33, the gate electrode 34, and the photo-resist 40 as a mask.

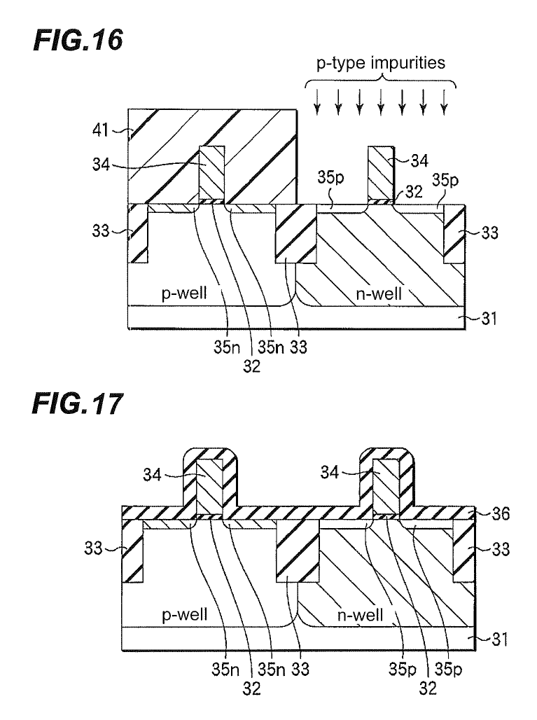

Next, as shown in FIG. 16, the photoresist 40 is removed through, for example, oxygen plasma ashing. Then, on the contrary at this time, a photoresist 41 is coated on the p-well, on which an nMOS transistor is to be formed. Thereafter, an extension 35p of the pMOS transistor is formed through the ion injection of p-type impurities, such as, for example, boron, into the exposed n-well by using the device isolation area 33, the gate electrode 34, and the photo-resist 41 as a mask.

Next, as shown in FIG. 17, the photoresist 41 is removed through, for example, oxygen plasma ashing. Then, a thin film 36, which is to be the side wall spacer, is formed on the entire surface of the semiconductor substrate 31 by using a CVD method, such as, for example a PECVD (Plasma-Enhanced CVD) method so that the thin film 36 is coated on the side surfaces and upper surfaces of the gate electrodes 34. In the present embodiment, the thin film 36 is a film containing the germanium, silicon, nitrogen, and hydrogen as described in the first or second embodiment, for example, a GeSiNH film. Of course, the thin film 36 may be the GeSiCNH film as described in the third embodiment.

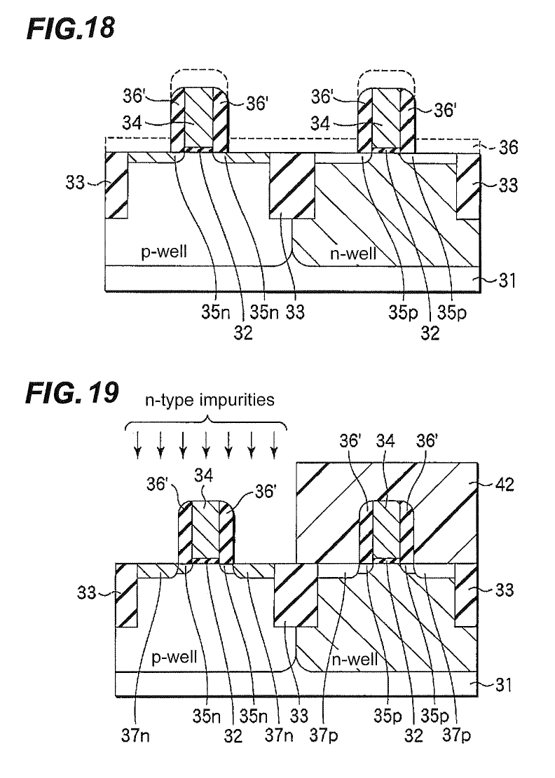

Next, as shown in FIG. 18, the thin film 36 is etched back through an anisotropic etching. An example of the anisotropic etching includes a Reactive Ion Etching (RIE). By etching back the thin film 36, side wall spacers 36 consisting of the GeSiNH film are formed on the side surfaces of the gate electrodes 34.

Next, as shown in FIG. 19, a photoresist 42 is coated on the n-well. Then, source/drain areas 37n of the nMOS transistor are formed through the ion injection of n-type impurities, such as, for example, arsenic, into the exposed p-well by using the device isolation areas 33, the gate electrodes 34, the side wall spacers 36′, and the photo-resist 42 as a mask.

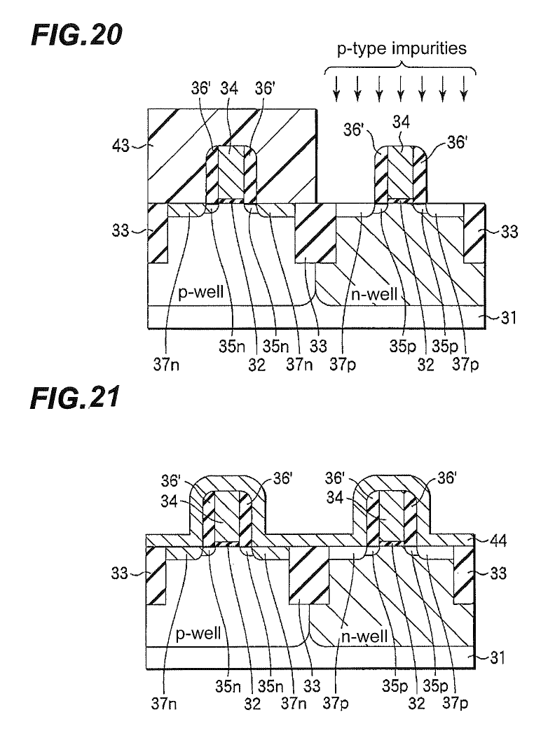

Next, as shown in FIG. 20, the photoresist 42 is removed, and a photoresist 43 is coated on the p-well. Then, source/drain areas 37p of the pMOS transistor are formed through the ion injection of p-type impurities, such as, for example, boron, into the exposed n-well by using the device isolation areas 33, the gate electrodes 34, the side wall spacers 36′, and the photo-resist 43 as a mask. Further, in the present embodiment, the photoresist 42 is removed through a wet etching using a sulfuric acid/hydrogen peroxide mixture solution (SPM), after performing the oxygen plasma ashing. The GeSiNH film has a property, which is not easily changed by the oxygen plasma ashing and is stable in the sulfuric acid/Hydrogen peroxide mixture solution. Therefore, in the wet etching for removing the photo-resist 42, careless removal of the side wall spacers 36′ is prevented.

Next, as shown in FIG. 21, the photoresist 43 is removed through, in the present embodiment, the oxygen plasma ashing and a wet etching using a sulfuric acid/hydrogen peroxide mixture solution. Then, in order to activate the source/drain areas 37n and 37p, they are subjected to a heat treatment at a high temperature of about 1000° C. through the spike RTA (Rapid Thermal Anneal). Then, the natural oxide film is removed using the DIE. As described above, the GeSiNH film is barely dissolved by the DHF even after the oxygen plasma ashing. Thereafter, a metal film 44 is formed on the entire surface of the semiconductor substrate 31 through, for example, the sputtering method, so that the metal film 44 is coated on the side surfaces and upper surfaces of the gate electrodes 34. In the present embodiment, the metal film 44 is a nickel film, which is formed with a thickness of 30 nm by the sputtering.

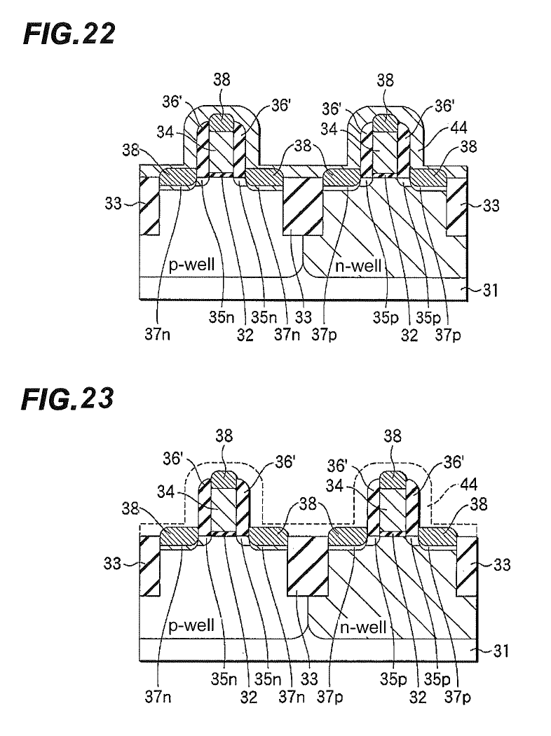

Next, as shown in FIG. 22, the structure with the metal film 44 as shown in FIG. 21 is subjected to a heat treatment for 30 seconds at 500° C. in the nitrogen atmosphere. As a result, reaction layers, nickel silicides 38 in the present embodiment, are formed on a portion, which reacts with a metal (nickel in the present embodiment) in the metal film 44 and a conductive material (silicon in the present embodiment) included in the semiconductor substrate 31, and at which the metal film 44 and the gate electrode 34 are in contact with each other, and a portion (the source/drain areas 37n and 37p within the semiconductor substrate 31 in the present embodiment) at which the metal film 44 and the semiconductor substrate 31 are in contact with each other. The formation of the nickel silicides 38 partially lowers the resistance of the gate electrode 34 and the source/drain areas 37n and 37p.

Next, as shown in FIG. 23, a non-reaction portion of the metal film 44 is removed by using an etching agent, which can easily etch the non-reaction portion of the metal film 44 and cannot easily etch the device isolation area 33, the resistance-lowered portion (nickel silicide 38) of the gate electrode 34, the resistance-lowered portion (nickel silicide 38) of the source/drain areas, and the side wall spacer 36′. As an example of such an etching agent, the sulfuric acid/hydrogen peroxide mixture solution may be used. In the present embodiment, the non-reaction portion of the metal film 44, that is, the nickel, is removed through a wet etching using the sulfuric acid/hydrogen peroxide mixture solution. As a result, the nickel silicide 38 remains on the gate electrode 34 and on the source/drain areas 37n and 3′7p. Since the side wall spacer 36′, which is a GeSiNH film, is not etched by the sulfuric acid/hydrogen peroxide mixture solution, the side wall spacers 36′ remain on the side surfaces of the gate electrode 34.

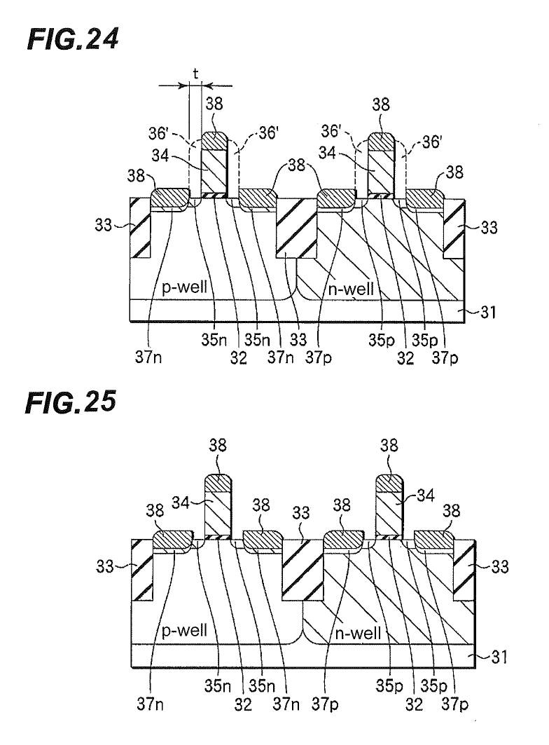

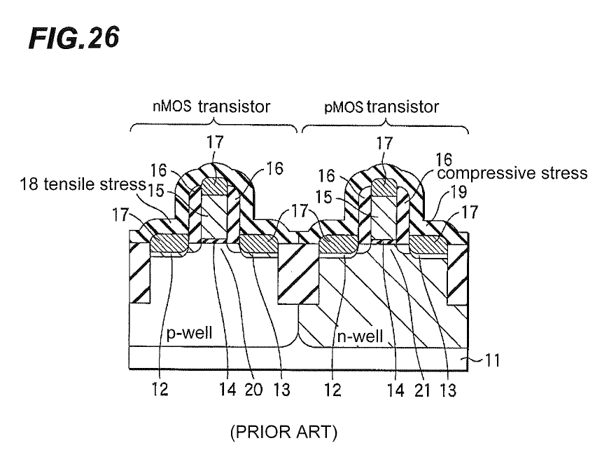

Next, as shown in FIG. 24, the side wall spacers 36′ are removed by using an etching agent, which can easily etch the side wall spacer 36′ and cannot easily etch the device isolation area 33, the resistance-lowered portion (nickel silicide 38) of the gate electrode 34, and the resistance-lowered portion (nickel silicide 38) of the source/drain areas. In the present embodiment, the structure with the non-reaction portion of the metal film 44 shown in FIG. 16 removed is dipped in the phosphoric acid (H₃PO₄). Since the side wall spacer 36′ has a horizontal thickness of 30 mm from the side surface of the gate electrode 34 and is isotropically etched, it can be removed within 30 seconds even in the case of over-etching.

Through the process described above, as shown in FIG. 25, it is possible to obtain a structure, a semiconductor device, in which the side wall spacers are removed from the side surfaces of the gate electrode 34, that is, which has no side wall spacer on the side surfaces of the gate electrode 34.

As shown in FIG. 25, in the structure formed according to an embodiment of the present invention, the nickel silicides 38 are not etched, the side wall spacers are removed, and SiN films are directly deposited around, for example, the gate. Therefore, in the structure formed according to an embodiment of the present invention, it is possible to more effectively apply a stress to the channel area, so as to improve the carrier mobility of the transistor.

Although the present invention has been described based on several embodiments, the present invention is not limited to the described embodiments and may have various modifications.

For example, the fourth embodiment described above discusses an example in which a thin film according to the first to third embodiments is applied to the side wall spacer that is used and then removed in the process of manufacturing a semiconductor device. However, the thin film removed in the process of manufacturing a semiconductor device is not limited to the side wall spacer. The thin film according to the first to third embodiments may be applied to a hard mask in the case of forming, for example, a via hole or a contact hole.

Further, although the fourth embodiment employs a semiconductor substrate 31 having an n-well and a p-well as an example of a semiconductor layer having an n-type semiconductor area and a p-type semiconductor area, the semiconductor layer is not limited to the semiconductor substrate 31 and may be a semiconductor thin film for forming a thin film transistor, or a so-called SOI substrate, which has a p-type semiconductor layer and an n-type semiconductor layer on, for example, an insulation film

Further, although the fourth embodiment shows an example forming both an nMOS transistor and a pMOS transistor, only one of the nMOS transistor and the pMOS transistor may be formed. In the latter case also, it is possible to omit the process of forming the photoresist 40, 41, 42, and 43 shown in FIGS. 15, 16, 19, and 20, and to introduce only one of n-type impurities and p-type impurities into the active area.

Further, although the extensions 35n and 35p are formed in the fourth embodiment, it is not always necessary to form the extensions 35n and 35p when the side wall spacer 36′ is formed. For example, in a transistor having a fine channel, the extensions 35n and the extensions 35p may contact each other during the heat treatment for activation, so as to cause a short-circuiting between the source and the drain. Therefore, the extensions 35n and 35p may be formed only when necessary.

Further, although the GeSiNH film or the GeSiCNH film is formed by using a parallel plate-type plasma CVD in the first to the fourth embodiments, they may be formed by another plasma CVD method. Further, the GeSiNH film or the GeSiCNH film is not limited to the plasma CVD and may be formed by using a thermal CVD, or other film formation methods, such as ALD and PVD, rather than the CVD.

The embodiments described above may have various modifications without departing from the scope and spirit of the invention.

According to the present invention, it is possible to provide a thin film and a method of manufacturing a semiconductor device by using the film, which can rapidly remove a thin film, such as a side wall spacer, used in the semiconductor device without etching the other films including nickel silicide.

What is claimed is:

1. A thin film used in a process of manufacturing a semiconductor device, wherein the thin film comprises germanium, silicon, nitrogen, and hydrogen.

2. The thin film as claimed in claim 1, wherein the thin film further comprises carbon in addition to the four elements.

3. The thin film as claimed in claim 1, wherein the thin film is formed by using a gas containing germanium and a nitrogen gas as a process gas, and adding a gas containing silicon to the process gas.

4. The thin film as claimed in claim 3, wherein the thin film is formed by controlling gas flow rate of the gas containing silicon and the nitrogen gas so that the gas flow rate ratio is larger than or equal to 4% and is smaller than or equal to 10%.

5. The thin film as claimed in claim 3, wherein the thin film is formed by controlling gas flow rate of the gas containing silicon and the nitrogen gas so that the gas flow rate ratio is larger than or equal to 5% and is smaller than or equal to 10%.

6. The thin film as claimed in claim 3, wherein the thin film is formed by controlling gas flow rate of the gas containing silicon and the nitrogen gas so that the gas flow rate ratio is larger than or equal to 4% and is smaller than or equal to 7%.

7. The thin film as claimed in claim 3, wherein the thin film is formed by controlling gas flow rate of the gas containing silicon and the nitrogen gas so that the gas flow rate ratio is larger than or equal to 4% and is smaller than or equal to 6%.

8. The thin film as claimed in claim 3, wherein the thin film is formed by controlling gas flow rate of the gas containing silicon and the nitrogen gas so that the gas flow rate ratio is larger than or equal to 5% and is smaller than or equal to 6%.

9. The thin film as claimed in claim 2, wherein the thin film is formed by using a gas containing germanium and a nitrogen gas as a process gas and adding a gas containing to silicon and a gas containing carbon to the process gas.

10. The thin film as claimed in claim 3, wherein the gas containing germanium is germane.

11. The thin film as claimed in claim 9, wherein the gas containing germanium is germane.

12. The thin film as claimed in claim 3, wherein the gas containing silicon is silane.

13. The thin film as claimed in claim 9, wherein the gas containing silicon is silane.

14. The thin film as claimed in claim 9, wherein the gas containing carbon is methane.

15. A method of manufacturing a semiconductor device, the method comprising:
forming the thin film defined in claim 1;
exposing the thin film to an etching; and
removing the thin film remaining after the etching.

16. A method of manufacturing a semiconductor device, comprising:
forming a gate electrode on an active area in a semiconductor layer including the active area and a device isolation area;
forming a side wall spacer on a side surface of the gate electrode by using the thin film defined in claim 1;
forming a pair of source-and-drain areas in the active area by injecting impurities in the active area by using the device isolation area, the gate electrode, and the side wall spacer as a mask;
coating a metal film on the semiconductor layer, the device isolation area, the side wall spacer, and the gate electrode;
reacting the metal film with the semiconductor layer and the gate electrode, so as to partially lower a resistance of the source-and-drain areas and the gate electrode;
removing a non-reacted portion of the metal film by using an etching agent, which can easily etch the non-reacted portion of the metal film and cannot easily etch the device isolation area, a resistance-lowered portion of the gate electrode, a resistance-lowered portion of the source-and-drain areas, and the side wall spacer; and
removing the side wall spacer by using an etching agent, which can easily etch the side wall spacer and cannot easily etch the device isolation area, the resistance-lowered portion of the gate electrode, and the resistance-lowered portion of the source-and-drain areas.

17. A method of manufacturing a semiconductor device, comprising:
forming a gate electrode on each of a first conductive active area and a second conductive active area in a semiconductor layer including the first conductive active area, the second conductive active area, and a device isolation area;
forming side wall spacers on side surfaces of the gate electrode formed on the first conductive active area and on side surfaces of the gate electrode formed on the second conductive active area by using the thin film defined in claim 1;
covering an area in the semiconductor layer, at which a first conductive transistor is formed, by using a first mask material;
forming a pair of second conductive source-and-drain areas in the first conductive active area by injecting impurities in the first conductive active area by using the device isolation area, the gate electrode formed on the first conductive active area, the side wall spacers formed on the gate electrode, and the first mask material as a mask;
removing the first mask material, and then covering an area in the semiconductor layer, at which a second conductive transistor is formed, by using a second mask material;
forming a pair of first conductive source-and-drain areas in the second conductive active area by injecting impurities in the second conductive active area by using the device isolation area, the gate electrode formed on the second conductive active area, the side wall spacers formed on the gate electrode, and the second mask material as a mask;
removing the second mask material and then coating a metal film on the semiconductor layer, the device isolation area, the side wall spacer, and the gate electrode;
reacting the metal film with the semiconductor layer and the gate electrode, so as to partially lower a resistance of the source-and-drain areas and the gate electrode;
removing a non-reacted portion of the metal film by using an etching agent, which can easily etch the non-reacted portion of the metal film and cannot easily etch the device isolation area, a resistance-lowered portion of the gate electrode, a resistance-lowered portion of the source-and-drain areas, and the side wall spacer; and
removing the side wall spacer by using an etching agent, which can easily etch the side wall spacer and cannot easily etch the device isolation area, the resistance-lowered portion of the gate electrode, and the resistance-lowered portion of the source-and-drain areas.

18. The method as claimed in claim 16, wherein the etching agent, which can easily etch the non-reacted portion of the metal film and cannot easily etch the device isolation area, the resistance-lowered portion of the gate electrode, the resistance-lowered portion of the source-and-drain areas, and the side wall spacer, is a mixture solution comprising sulfuric acid and hydrogen peroxide.

19. The method as claimed in claim 17, wherein the etching agent, which can easily etch the non-reacted portion of the metal film and cannot easily etch the device isolation area, the resistance-lowered portion of the gate electrode, the resistance-lowered portion of the source-and-drain areas, and the side wall spacer, is a mixture solution comprising sulfuric acid and hydrogen peroxide.

20. The method as claimed in claim 16, wherein the etching agent, which can easily etch the side wall spacer and cannot easily etch the device isolation area, the resistance-lowered portion of the gate electrode, and the resistance-lowered portion of the source-and-drain areas, is phosphoric acid.

21. The method as claimed in claim 17, wherein the etching agent, which can easily etch the side wall spacer and cannot easily etch the device isolation area, the resistance-lowered portion of the gate electrode, and the resistance-lowered portion of the source-and-drain areas, is phosphoric acid.

22. The method as claimed in claim 16, wherein the metal film comprises nickel.

23. The method as claimed in claim 17, wherein the metal film comprises nickel.
